(19) United States
(12) Patent Application Publication
(10) Pub. No.: US 2026/0047363 A1
(43) Pub. Date: Feb. 12, 2026

(54) METHOD, SYSTEM AND APPARATUS FOR FORMING AN OXIDE LAYER

(71) Applicant: ASM IP Holding B.V., Almere (NL)

(72) Inventors: Kamesh Mullapudi, Tempe, AZ (US); Austin Way, Scottsdale, AZ (US); Eric James Shero, Phoenix, AZ (US); Jessica Akemi Cimada da Silva, Chandler, AZ (US); Devika Choudhury, Chandler, AZ (US); Yu Xu, Mesa, AZ (US); Xiangdong Qin, Chandler, AZ (US); Jereld Lee Winkler, Gilbert, AZ (US); Mihaela Balseanu, Scottsdale, AZ (US)

(21) Appl. No.: 19/291,731

(22) Filed: Aug. 6, 2025

Related U.S. Application Data
(60) Provisional application No. 63/681,701, filed on Aug. 9, 2024.

(51) Int. Cl. H01L 21/02; C23C 16/40; C23C 16/455

(52) U.S. Cl. CPC H01L 21/0228; C23C 16/403; C23C 16/45527; C23C 16/45553; H01L 21/02178

(57) ABSTRACT

A method for depositing an oxide on a substrate, comprising: a) providing the substrate in a chamber; b) initially pulsing a precursor into the chamber to chemisorb a constituent onto a surface of the substrate; c) pulsing an oxygen species into the chamber to form an oxide layer on the surface upon contact with the constituent, wherein the oxygen species comprises an alcohol; and repeating one or more steps b)-c) until the oxide layer is deposited to a desired thickness.

### CROSS-REFERENCE TO RELATED APPLICATIONS

This application is a nonprovisional of, and claims priority to and the benefit of, U.S. Provisional Patent Application No. 63/681,701, filed Aug. 9, 2024 and entitled “METHOD, SYSTEM AND APPARATUS FOR FORMING AN OXIDE LAYER,” which is hereby incorporated by reference herein.

### FIELD OF THE DISCLOSURE

The present disclosure generally relates to methods and systems suitable for forming electronic devices. More particularly, the disclosure relates to methods and systems that can be used for depositing a material in gaps, trenches, and the like.

### BACKGROUND OF THE DISCLOSURE

The scaling of semiconductor devices has led to significant improvements in speed and density of integrated circuits. However, with miniaturization of wiring pitch in large scale integration devices, void-free filling of high aspect ratio gaps or trenches and/or deposition processes for maintaining the integrity of underlayer metals (e.g., a bottom electrode) becomes increasingly difficult due to limitations of existing deposition processes. Thus, there is a need for processes that efficiently fill high aspect ratio features, e.g., gaps such as trenches on semiconductor substrates, and/or reducing the risk of damage to underlying layers for example in the context of logic and/or memory devices. There is a particular need for processes that efficiently fill high aspect ratio features with conductive materials that minimize seam and gap formation.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Disclosed here are method, system and apparatus for depositing an oxide in a recess of a substrate, comprising: providing the substrate in a chamber, the substrate including at least one opening to the recess wherein the at least one opening is bordered by a perimeter in a surface area adjacent to and outside of the recess, wherein the recess comprises an inner surface;
pulsing a precursor into the chamber to chemisorb to the inner surface within the recess;
pulsing an oxygen species comprising a first alcohol into the chamber to form the oxide within the recess upon contact with the chemisorbed precursor;
pulsing an inhibitor into the chamber to preferentially deposit the inhibitor in a portion of the recess adjacent to the at least one opening and on at least a portion of the surface area; and
repeating steps b)-d) to deposit the oxide to a desired thickness level within the recess.

In some examples, the inhibitor is a second alcohol. In some examples, the first alcohol and the second alcohol are the same. In some examples, the first alcohol and the second alcohol are different. In some examples, the oxide is a metal oxide. In some examples, the method includes pulsing an inert gas into the chamber to purge the chamber subsequent to one or more of steps b)-d). In some examples, pulsing the inhibitor to preferentially deposit the inhibitor at the at least one opening further comprises pulsing the inhibitor for a first time period and pulsing the oxygen species for a second time period, wherein the first time period is shorter than the second time period.

In some examples, pulsing the inhibitor to preferentially deposit the inhibitor further comprises selecting the inhibitor to have a first partial pressure below a second partial pressure of the oxygen species. In some examples, the method further comprises adding an inert gas pulse to an inhibitor pulse or an oxygen species pulse to tune the first partial pressure or the second partial pressure. In some examples, pulsing the inhibitor to preferentially deposit the inhibitor further comprises pulsing the inhibitor at a first concentration and pulsing the oxygen species at a second concentration, wherein the first concentration is less than the second concentration.

In some examples, the method further comprises pulsing the inhibitor and the oxygen species simultaneously. In some examples the inhibitor and the oxygen species are both tertbutyl alcohol. In some examples wherein pulsing the inhibitor and the oxygen species simultaneously further comprises selecting the inhibitor to have a first partial pressure between below a second partial pressure of the oxygen species, wherein the first partial pressure and the second partial pressure are between 10 mTorr to 1 Torr. In some examples wherein pulsing the inhibitor and the oxygen species simultaneously further comprises selecting the inhibitor to have a first molecular mass greater than a second molecular mass of the oxygen species. In some examples wherein pulsing the inhibitor and the oxygen species simultaneously further comprises pulsing the inhibitor at a first concentration and pulsing the oxygen species at a second concentration, wherein the first concentration is less than the second concentration, wherein the first concentration and the second concentration are between about 1% to 50% or about 15-25%.

In some examples wherein the first concentration is between 1% and 50%.

In some examples the method further comprises depositing a higher flux of the inhibitor proximate the at least one opening on at least a portion of the perimeter surface area compared to the bottom surface or the opposing side walls, or a combination thereof. In some examples deposition of the inhibitor at the higher flux in a region proximate the at least one opening creates a concentration gradient of the inhibitor from the perimeter in the surface area to a depth within the recess, wherein the greatest concentration of the inhibitor is at the surface area wherein the concentration decreases as the depth of the recess increases. In some examples the first width is less than the second width. In some examples the opposing sidewalls form an inverse taper from the second width to the first width at the at least one opening. In some examples the second width is a widest portion of the recess measured between the opposing sidewalls. In some examples the recess comprises a via having two openings, wherein the recess extends into a depth of the substrate and the inner surface of the recess includes opposing side walls.

Further disclosed are method, system and apparatus for depositing an oxide on a substrate, comprising: a) providing the substrate in a chamber; b) initially pulsing a precursor into the chamber to chemisorb a constituent onto a surface of the substrate; c) pulsing an oxygen species into the chamber to form an oxide layer on the surface upon contact with the constituent, wherein the oxygen species comprises an alcohol; and repeating one or more steps b)-c) until the oxide layer is deposited to a desired thickness.

In some examples the substrate comprises silicon or germanium, or a combination thereof (SiGe). In some examples the substrate comprises SiGe comprising a Ge concentration of 15% to 45%. In some examples the precursor is a metal-containing precursor. In some examples the oxide is a metal oxide. In some examples the alcohol is tertbutyl alcohol, methanol (MeOH), ethanol (EtOH), n-propanol (n-PrOH), or butanol (t-BuOH, n-BuOH), 1-propanol (C3H7OH), 1-butanol (C4H9OH), 1-pentanol (C5H11OH), 2-butanol (C4H10O), 2-pentanol (C5H12O), 2-hexanol (C6H14O), 2-heptanol (C7H16O), 2-methyl-2-butanol (C5H12O), 3-methyl-3-pentanol (C6H14O), 3-ethyl-3-pentanol (C7H16O), 3-methyl-3-hexanol (C7H16O), or a combination thereof. In some examples further comprising pulsing an inert gas into the chamber to purge the chamber subsequent to one or more of steps b)-d). In some examples the desired thickness is less than 50 angstroms. In some examples the desired thickness is less than 35 angstroms.

A structure may be formed according to the disclosed method. In some examples the surface comprises a recess. In some examples the structure is a semiconductor device having a CMOS, finFET, GAA or CFET architecture.

For the purpose of summarizing the disclosure and the advantages achieved over the prior art, certain objects and advantages of the disclosure have been described herein above. Of course, it is to be understood that not necessarily all such objects or advantages can be achieved in accordance with any particular embodiment or example of the disclosure. Thus, for example, those skilled in the art will recognize that the examples disclosed herein can be carried out in a manner that achieves or optimizes one advantage or group of advantages as taught or suggested herein without necessarily achieving other objects or advantages as can be taught or suggested herein.

All of these examples are intended to be within the scope of the disclosure. These and other embodiments will become readily apparent to those skilled in the art from the following detailed description of certain examples having reference to the attached figures, the disclosure not being limited to any particular example(s) discussed.

### BRIEF DESCRIPTION OF THE DRAWING FIGURES

While the specification concludes with claims particularly pointing out and distinctly claiming what are regarded as embodiments or examples of the disclosure, the advantages of examples of the disclosure may be more readily ascertained from the description of certain examples of the disclosure when read in conjunction with the accompanying drawings. Elements with the like element numbering throughout the figures are intended to be the same.

FIG. 1A illustrates a schematic diagram of a reactor system, in accordance with an example of the present technology.

FIG. 1B illustrates a schematic diagram of a reactor system having multiple reaction chambers, in accordance with an example of the present technology.

FIG. 2A illustrates a device structure, in accordance with an example of the present technology.

FIG. 2B illustrates a device structure, in accordance with an example of the present technology.

FIG. 2C illustrates a device structure, in accordance with an example of the present technology.

FIG. 3 illustrates a device structure, in accordance with an example of the present technology.

FIG. 4 illustrates a device structure, in accordance with an example of the present technology.

FIG. 5 illustrates a device structure, in accordance with an example of the present technology.

FIG. 6A illustrates a processing method, in accordance with an example of the present technology.

FIG. 6B illustrates a processing method, in accordance with an example of the present technology.

FIG. 7 illustrates a processing method, in accordance with an example of the present technology.

FIG. 8 illustrates a processing method, in accordance with an example of the present technology.

FIG. 9A illustrates a device structure, in accordance with an example of the present technology.

FIG. 9B illustrates a processing method, in accordance with an example of the present technology.

### DETAILED DESCRIPTION

The detailed description of various examples herein makes reference to the accompanying drawings, which show the exemplary examples by way of illustration. While these exemplary examples are described in sufficient detail to enable those skilled in the art to practice the disclosure, it should be understood that other examples may be realized and that logical, chemical, and/or mechanical changes may be made without departing from the spirit and scope of the disclosure. Thus, the detailed description herein is presented for purposes of illustration only and not of limitation. For example, the steps recited in any of the method or process descriptions can be executed in any combination and/or order and are not limited to the combination and/or order presented. Further, one or more steps from one of the disclosed methods or processes can be combined with one or more steps from another of the disclosed methods or processes in any suitable combination and/or order. Moreover, any of the functions or steps can be outsourced to or performed by one or more third parties. Furthermore, any reference to singular includes plural examples, and any reference to more than one component can include a singular example.

Although certain embodiments and examples are disclosed below, it will be understood by those in the art that the disclosure extends beyond the specifically disclosed examples and/or uses of the disclosure and obvious modifications and equivalents thereof. Thus, it is intended that the scope of the disclosure should not be limited by the particular examples described herein.

The illustrations presented herein are not meant to be actual views of any particular material, apparatus, structure, or device, but are merely representations that are used to describe examples of the disclosure.

As used herein, the term “substrate” can refer to any underlying material or materials that may be used, or upon which, a device, a circuit, or a film/layer may be formed.

As used herein, the term “atomic layer deposition” (ALD) can refer to a vapor deposition process in which deposition cycles, preferably a plurality of consecutive deposition cycles, are conducted in a process chamber. Typically, during each cycle the precursor is chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, if necessary, a reactant (e.g., another precursor or reaction gas) can subsequently be introduced into the process chamber for use in converting the chemisorbed precursor to the desired material on the deposition surface. Typically, this reactant is capable of further reaction with the precursor. Further, purging steps can also be utilized during each cycle to remove excess precursor from the process chamber and/or remove excess reactant and/or reaction byproducts from the process chamber after conversion of the chemisorbed precursor. Further, the term “atomic layer deposition,” as used herein, is also meant to include processes designated by related terms such as, “chemical vapor atomic layer deposition”, “atomic layer epitaxy” (ALE), molecular beam epitaxy (MBE), gas source MBE, or organometallic MBE, and chemical beam epitaxy when performed with alternating pulses of precursor composition(s), reactive gas, and purge (e.g., inert carrier) gas.

As used herein, the term “chemical vapor deposition” (CVD) can refer to any process wherein a substrate is exposed to one or more volatile precursors, which react and/or decompose on a substrate surface to produce a desired deposition.

As used herein, the terms “layer,” “film,” and/or “thin film” can refer to any continuous or non-continuous structures and material deposited by the methods disclosed herein. For example, “layer,” “film,” and/or “thin film” could include 2D materials, nanorods, nanotubes, or nanoparticles or even partial or full molecular layers or partial or full atomic layers or clusters of atoms and/or molecules. “Layer,” “film,” and/or “thin film” can comprise material or a layer with pinholes, but still be at least partially continuous.

Further, in this disclosure, any two numbers of a variable can constitute a workable range of the variable, and any ranges indicated can include or exclude the endpoints. Additionally, any values of variables indicated (regardless of whether they are indicated with “about” or not) can refer to precise values or approximate values and include equivalents, and can refer to average, median, representative, majority, or the like. Further, in this disclosure, the terms “including,” “constituted by” and “having” can refer independently to “typically or broadly comprising,” “comprising,” “consisting essentially of,” or “consisting of” in some examples. In this disclosure, any defined meanings do not necessarily exclude ordinary and customary meanings in some examples.

Referring now to 1, in various examples, a reactor system 150 can comprise a reaction chamber 104, a susceptor 106 to hold a substrate 130) during processing, a fluid distribution system (e.g., a showerhead 108) to distribute one or more reactants to a surface of substrate 130, one or more reactant sources 110, 112, and/or 113, and/or a carrier and/or purge gas source 114, fluidly coupled to reaction chamber 104 via respective lines 116, 118, 119 and 120, and respective valves or flow controllers 122, 123, 125 and 126. Substrate 130 may include at least one recess 31. Reactant gases (e.g., precursor 115, oxygen species 117 and inhibitor 121) or other materials from respective sources 110, 112, and/or 113 can be applied to substrate 130 in reaction chamber 104. In an example, oxygen species 117 and inhibitor 121 may comprise the same chemical and may be drawn from the same source vessel (e.g., source 112 or source 113). In another example, oxygen species 117 and inhibitor 121 may comprise different chemicals and may be drawn from different same source vessels (e.g., source 112 and/or source 113). Purge/carrier gas 124 from gas source 114 can be flowed to and through reaction chamber 104 to act as a carrier gas, and/or purge or remove any excess reactant or other undesired materials from reaction chamber 104. Reactor system 150 can also comprise a vacuum source 128 fluidly coupled to the reaction chamber 104, which can be configured to evacuate reactants, a purge gas, or other materials out of reaction chamber 104.

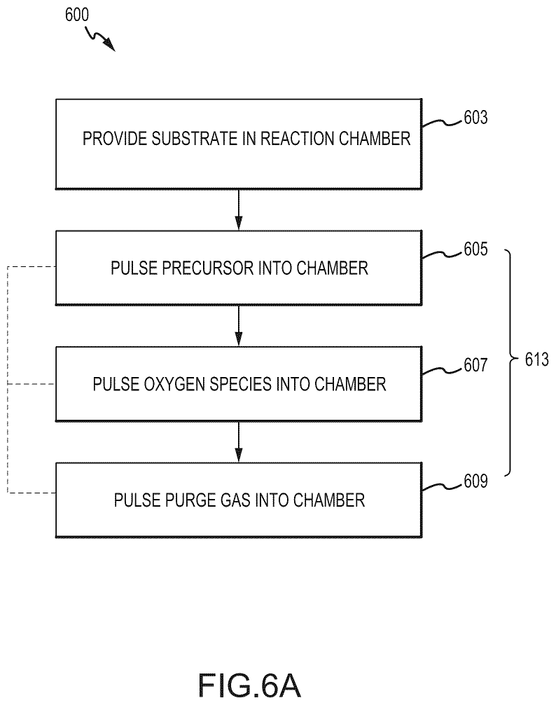

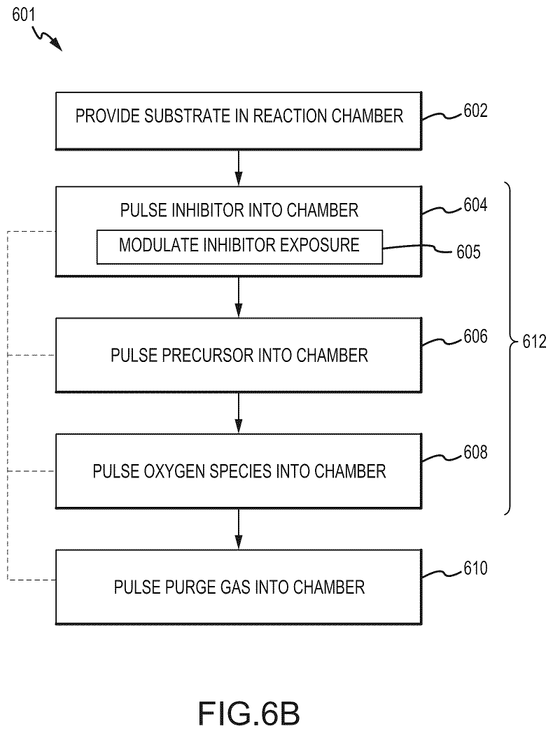

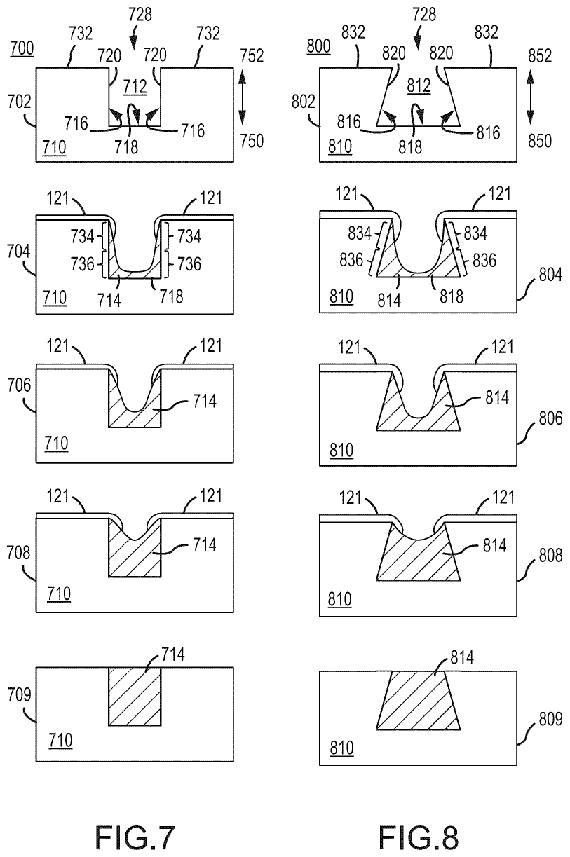

Controller 152 can be configured to perform various functions and/or steps as described herein. Controller 152 can include one or more microprocessors, memory elements, and/or switching elements to perform the various functions. Although illustrated as a single unit, Controller 152 can alternatively comprise multiple devices. By way of example, Controller 152 can be used to control gas flow (e.g., by monitoring flow rates and controlling valves 122, 123, 125 and/or 126), motors, heaters, cooling devices and/or vacuum source 128 to execute various processes (e.g., methods 600, 601, 700, 800 and/or 900 shown in respective FIG. 6A, FIG. 6B, FIG. 7, FIGS. 8 and/or 9). Further, when a system includes two or more reaction chambers, as described in more detail below, the two or more reaction chambers can be coupled to the same/shared controller.

In an example, an oxide deposition process may be performed by reactor system 150 to deposit an oxide on a surface 153 of substrate 130. In an example, a gap filling process may be performed by reactor system 150 to deposit an oxide within one or more recess 31 of substrate 130. The process may comprise pulsing precursor 115 from reactant source 110 to reaction chamber 104 via showerhead 108.

In an example, oxygen species 117 may comprise an alcohol and may be pulsed with or separately from precursor 115 from source 112 to reaction chamber 104 via showerhead 108. As precursor 115 and oxygen species 117 contact substrate 130 an oxide may form on substrate 130 and/or within recess 31.

In an example, to inhibit deposition of an oxide on surface 153 and/or at the top and/or outside of recess 31, an inhibitor 121 may also be pulsed into chamber 104. In an example, inhibitor 121 may comprise any of a variety of inhibitors, for example, inhibitor 121 may comprise the same chemical as oxygen species 117 and may be pulsed into chamber 104 from a same source vessel (e.g., source 112). In particular, inhibitor 121 may be a first alcohol and oxygen species 117 may be a second alcohol that is the same as the first alcohol. In an example, inhibitor 121 may comprise a different chemical from oxygen species 117. In particular, inhibitor 121 may be a first alcohol and oxygen species 117 may be a second alcohol that is a different alcohol from the first alcohol. Inhibitor 121 may be pulsed into chamber 104 from a different source vessel (e.g., source 113) than source 112 storing oxygen species 117. Inhibitor 121 may be pulsed into the chamber 104 separately from precursor 115 and/or oxygen species 117 or simultaneously with one or more of the precursor 115 and/or the oxygen species. In an example, inhibitor 121 may be flowed into chamber 104 subsequent to flowing oxygen species 117 into chamber 104. In another example, inhibitor 121 may be flowed into chamber 104 simultaneously with flowing oxygen species 117 into chamber 104. In another example, inhibitor 121 may be flowed into chamber 104 prior to flowing oxygen species 117 into chamber 104.

Inhibitor 121 may be selected to preferentially deposit at an opening of the recess 31 so as to prevent oxide from forming at the opening to the recess 31 to a greater extent than within recess 31. Reduction in oxide layer deposition at the opening of recess 31 may reduce formation of gaps or seams in oxide deposited therein.

In an example, oxide materials such as precursor 115 and oxygen species 117 may be deposited in the same chamber as inhibitor 121 or may be deposited in different chambers.

The oxide layer or gap fill may be formed by any of a variety of methods including various deposition cycles including pulsing precursor 115, inhibitor 121 and/or oxygen species 117 into the chamber 104 and purging the chamber with a purge gas 124 between one or more pulses and/or between one or more deposition cycles. Such a deposition cycle (or portions thereof) may be repeated until a desired thickness of deposited oxide is disposed on a surface 153 of the substrate 130 and/or within recess 31 of substrate 130. Precursor 115, inhibitor 121 and/or oxygen species 117 may be pulsed into the chamber in any appropriate sequence. The order of such pulses and number of pulses may vary.

One or more of precursor 115, oxygen species 117 and/or inhibitor 121 may be pulsed simultaneously. For example, a deposition cycle for forming an oxide layer on surface 153 of the substrate 130 and/or within recess 31 of substrate 130 may comprise first pulsing a precursor 115 into chamber 104, then purging chamber 104 with purge gas 124, then pulsing oxygen species 117 comprising an alcohol into chamber 104, then purging chamber 104 with purge gas 124 at various intervals, and repeating the deposition cycle until reaching a desired thickness of the oxide layer on surface 153 of the substrate 130 and/or a desired depth of the oxide layer within recess 31 of substrate 130. In another example, a deposition cycle for forming an oxide layer on surface 153 of the substrate 130 and/or within recess 31 of substrate 130 may comprise pulsing inhibitor 121 into chamber 104 to inhibit deposition of an oxide on surface 153 and/or at various areas on outer portions or top portions of recess 31, precursor 115 may then be pulsed into chamber 104, purging chamber 104 with purge gas 124, then pulsing inhibitor 121, then purging chamber 104 with purge gas 124 and finally pulsing oxygen species 117 into chamber 104. In an example, use of an inhibitor 121 to form an oxide layer on surface 153 may reduce incidence of island formation on surface 153 during deposition of the oxide layer and/or may promote formation of a continuous film, possibly faster than without an inhibitor.

In an example, chamber 104 may be purged with purge gas 124 at various intervals (e.g., between pulses or deposition cycles), and repeating the deposition cycle until reaching a desired thickness of the oxide layer on surface 153 of the substrate 130 and/or a desired depth of the oxide layer within recess 31 of substrate 130. In another example, an oxide layer may be deposited on a surface 153 of substrate 130 or may be deposited within a recess 31 of substrate 130 by first contacting substrate 130 with precursor 115, then contacting substrate 130 with oxygen source 117 comprising an alcohol (e.g., to terminate the surface 153 with OH groups), then, optionally, contacting substrate 130 with inhibitor 121 comprising an alcohol (e.g., to contact or dispose near surface OH groups).

In an example, where inhibitor 121 and oxygen species 117 are the same alcohol, deposition of an oxide layer may include wherein a first partial pressure of the inhibitor 121 may be different from a second partial pressure of oxygen source 117. In some examples, the partial pressure of the inhibitor 121 may be lower than the partial pressure of the oxygen species 117, doing so may establish an inhibition gradient on substrate 130 (e.g., from a top portion of recess 31 to a bottom portion of recess 31). In an example, reactor system 150 may comprise a multisource pulsed valve manifold (PVM) 151 configured to add inert gas (e.g., carrier/purge gas 124) to a pulse of inhibitor 121 and/or oxygen species 117 to raise or lower partial pressure.

In another embodiment, wherein the inhibitor 121 and oxygen species 117 are the same alcohol, a pulse time of the inhibitor 121 may be of shorter duration than a pulse time of the oxygen species 117. In an example, where inhibitor 121 and oxygen species 117 are the same alcohol, deposition of an oxide layer may include wherein a first process temperature of the inhibitor 121 may be different from a second process temperature of oxygen source 117. In some examples, the first process temperature may be lower than the second process temperature.

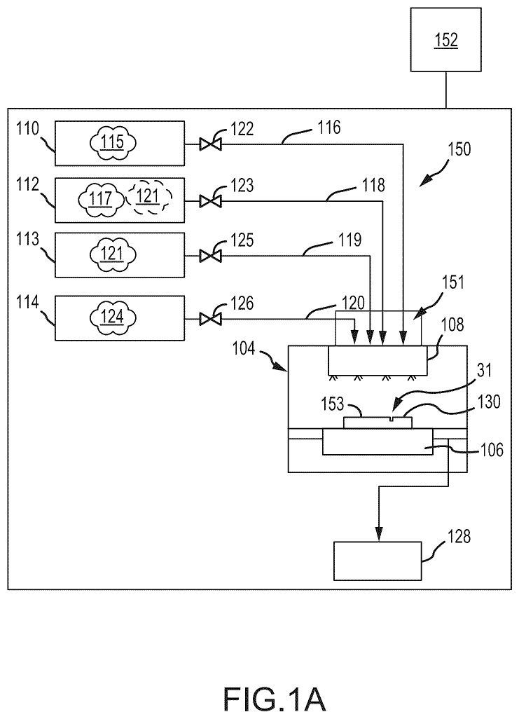

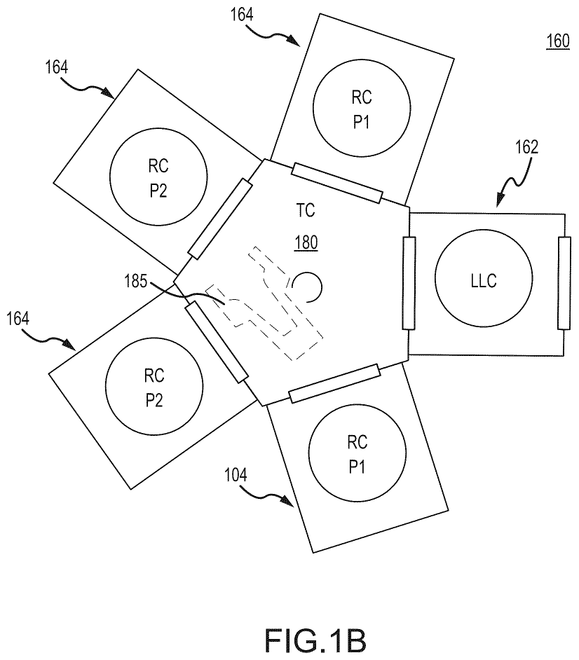

In some examples, a reactor system (e.g., reactor system 150) can comprise multiple reaction chambers. For example, in reactor system 160, shown in FIG. 1B, a number of reaction chambers 104 and 164 (each of which can be an example of reaction chamber 104 in FIG. 1A) can be disposed around and/or coupled to a transfer chamber 180 comprising a transfer tool 185 for transferring substrates between reaction chambers 104 and/or 164. Substrates can be transferred from a load lock chamber 162 and between reaction chambers 104 and/or 164 (e.g., through transfer chamber 180). For example, a substrate 130 can be disposed in different chambers for different steps of a semiconductor manufacturing process (e.g., etching, oxidizing, passivation, and/or deposition steps may each be performed in the same or different chambers).

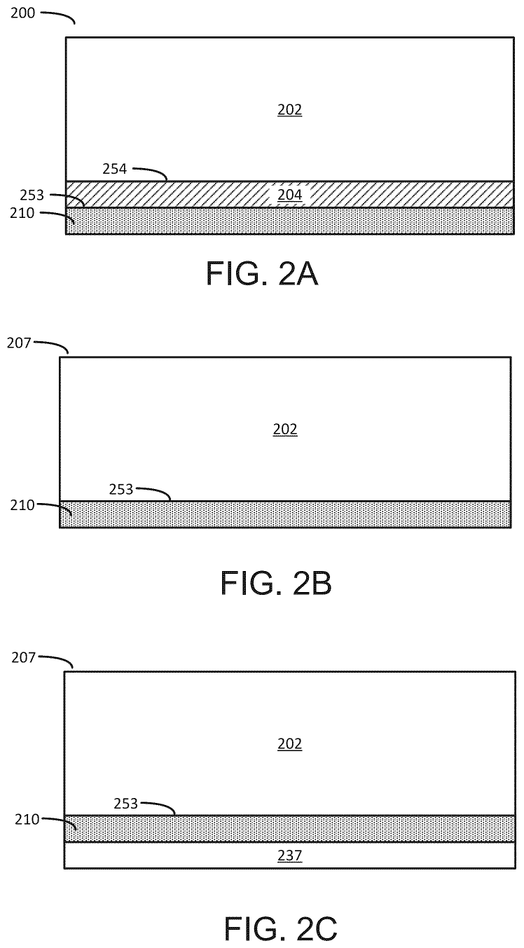

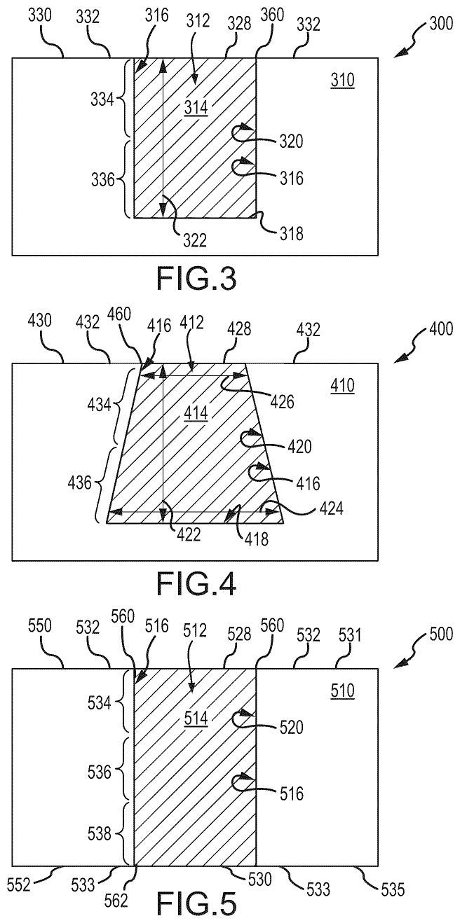

FIG. 2A illustrates a structure 200 in accordance with examples of the disclosure. Device structure 200 can be any of a variety of semiconductor structures comprising an oxide layer 202 formed over a substrate 210. In an example, substrate 210 may comprise any of a variety of materials. In certain embodiments, substrate 210 comprises silicon germanium (SiGe). The concentration of germanium (Ge) in substrate 210 may vary from about 10% to about 65%, or about 12% to about 60%, or about 13% to about 55%, or about 14% to about 50%, or about 15% to about 45%, or about 16% to about 40%, or about 17% to about 35%, or any appropriate concentration (here “about” means+/−5%). In some examples, during deposition of oxide layer 202, substrate 210 may be exposed to an oxygen species. Exposure to a conventional H2O and/or O3-based oxygen species during deposition of oxide layer 202 may result in formation of SiO and/or GeO in an oxide layer 204 comprising SiOx and GeOx or a Ge rich SiOx layer 204 at an interface between substrate surface 253 and oxide layer 202. The concentration of Ge in substrate 210 can be correlated to a propensity to oxidize to GeO at the interface. Since GeO is volatile, for subsequent process steps, GeO can outgas from underneath the oxide 202 (e.g., where structure 200 includes oxide layer 202 comprising an epi hard mask) and damage oxide layer 202, resulting in defects (e.g., inline defects). Without being bound by theory, using an alcohol as the oxygen source 117 may lower surface oxidation on SiGe during oxide layer 202 deposition. Thus, use of alcohol as an oxygen species 117 may reduce defectivity of structure 200 related to formation of GeO. For applications that require high aspect ratio conformality as well as integrity of underlayer metals (e.g., a bottom electrode 237, see FIG. 2C) such a process may reduce defectivity is such structures as well (see FIG. 3 to FIG. 5).

FIG. 2B illustrates a structure 207 in accordance with examples of the disclosure. In an example, a hard mask layer comprising an oxide layer 202 (e.g., an aluminum oxide (AlOx)) may be deposited directly on surface 253 of the substrate 210. In such examples, the oxide layer 202 may be deposited by oxide deposition processes described here using an alcohol as an oxygen species 117. In some examples, an inhibitor 121 may be used. In some examples, the inhibitor 121 may comprise an alcohol.

In various examples, substrate 210 may comprise a planar surface and/or comprise features formed into or onto a surface 253 of substrate 210. In some examples, such features may have a high aspect ratio (e.g., aspect ratios of about 4 or higher) or complex morphology as illustrated at least in FIG. 3 to FIG. 5.

FIG. 3 illustrates a structure 300 in accordance with examples of the disclosure. Device structure 300 can be any of a variety of semiconductor structures. In various examples, substrate 310 features may be formed into or onto a surface 330 of substrate 310, for example, a three-dimensional structure such as a recess 312 may for a portion of FinFETS or gate-all-around (GAA) FETS and/or memory elements. In some examples structure 300 may have a high aspect ratio (e.g., aspect ratios of about 4 or higher) or complex morphology.

In an example, structure 300 includes a substrate 310 having a recess 312. Recess 312 may have a top portion 334 and a lower portion 336. Recess 312 may extend a depth 322 from opening 328 to bottom surface 318 and may be filled with an oxide layer 314. Recess 312 may be bordered by a perimeter 360 in surface area 332 about opening 328. Recess 312 may also include an inner surface 320 comprising sidewalls surfaces 316 and a bottom surface 318. Opposing sidewall surfaces 316 may be substantially parallel. Structure 300 may be formed according to examples described herein.

FIG. 4 illustrates a structure 400 in accordance with examples of the disclosure. Device structure 400 can be any of a variety of semiconductor structures. In various examples, substrate 410 features may be formed into or onto a surface 430 of substrate 410, for example, a three-dimensional structure such as a recess, cavity, or trench, or a combination thereof. Such a patterned substrate 410 may comprise partially fabricated semiconductor device structures, such as, for example, transistors (e.g., such as FinFETS or gate-all-around (GAA) FETS) and/or memory elements. In some examples the structures may have high aspect ratios (e.g., aspect ratios of about 4 or higher) or complex morphology.

In an example, structure 400 includes a substrate 410 having a recess 412. Recess 412 may have a top portion 434 and a lower portion 436. Recess 412 may be filled with an oxide 414. Recess 412 may be bordered by a perimeter 460 in surface area 432 near opening 428. Recess 412 may also include inner surface 420 comprising sidewalls surfaces 416 and a bottom surface 418. Recess 412 may extend a depth 422 into recess 412. Opposing sidewalls 416 may be angled such that recess 412 is an inverse taper extending from opening 428 to bottom surface 418. In such an example, width 424 of bottom surface 418 is greater than width 426 of opening 428. Structure 400 may be formed according to examples described herein.

FIG. 5 illustrates a structure 500 in accordance with examples of the disclosure. Device structure 500 can be any of a variety of semiconductor structures (e.g., gate-all-around (GAA) structure). In various examples, substrate 510 features may be formed into or onto a surface 531 and/or 535 of substrate 510 (e.g., a three-dimensional structure such as a hole or via). Such a patterned substrate 510 may comprise partially fabricated semiconductor device structures, such as, for example, transistors (e.g., such as FinFETS or gate-all-around (GAA) FETS) and/or memory elements. In some examples the structures may have high aspect ratios (e.g., aspect ratios of about 4 or higher) or complex morphology.

In an example, structure 500 includes a substrate 510 having a recess 512. Recess 512 may have outer portions 534 and 538 and an inner portion 536. Recess 512 may be filled with an oxide 514. Recess 512 may be bordered on a first side 550 by a perimeter 560 in surface area 532 and on an opposite side 552, recess 512 may be bordered by perimeter 562 in surface area 533. Surface area 532 may be disposed in a plane about perimeter 560 of recess 512 proximate opening 528. Surface area 533 may be disposed in a plane about perimeter 562 of recess 512 near opening 5530. Recess 512 may also include an inner surface 520 comprising sidewalls surfaces 516. Recess 512 may extend from opening 528 through to opening 530 to form a hole or via in substrate 510. Opposing sidewall surfaces 516 may be parallel or have a different geometry. Structure 500 may be formed according to examples described herein.

ST), and strontium bismuth tantalate (SBT). Such precursors may comprise, for example, trimethylaluminum (TMA), dimethylaluminum hydride (DMAH), dimethylaluminum isopropoxide (DMAI), dimethylethylaminealane (DMEAA), trimethylaminealane (TEAA), N-methylpyrroridinealane (MPA), tri-isopropoxide aluminum, tri-isobutylaluminum (TIBA), and tritertbutylaluminum (TTBA), diethyl zinc (DEZ), tetraisopropyl orthotitanate (TTIP), titanium tetrachloride (TiCl4), tetrakis (dimethylamino) titanium (TDMAT), tetrakis(dimethylamino)zirconium (IV) (TDMAZ), magnesocene (Mg—(Cp)2), dimethylzinc (ZnMe2), diethylzinc (ZnEt2), methylzinc isopropoxide (ZnMe(OPr)), or zinc acetate (Zn(CH3CO2)2, halfnium chloride (HfCl4), and/or zirconium(IV) chloride (ZrCl4), or the like or combinations thereof, or any other appropriate precursor.

In other examples, precursor 115 may be a lanthanide-containing precursor for forming of lanthanide oxides, i.e., oxides of physically stable “rare earth” metallic elements such as scandium (Sc), yttrium (Y), lanthanum (La), cerium Ce, praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb) and lutetium (Lu), as well as silicon nitride (SiN). Such precursors may comprise, for example, 2,2,6,6-tetramethyl-3,5-heptane-dionate(III) lanthanum (La(thd)3), tris(cyclopentadienyl)lanthanum(III) (La(Cp)3), tris(isopropylcyclopentadienyl)lanthanum(III) (La(iPrCp)3) and/or tris(N,N′-diisopropylacetamidinato)scandium (Sc(amd)3), or the like or combinations thereof, or any other appropriate precursor.

In an example, precursor 115 can be pulsed into the reaction chamber for any suitable duration (e.g., for pulse times of between 0.05 to 200 seconds). The pressure within the reaction chamber during provision of precursor 115 can be any suitable pressure, such as between 1 and 10 Torr. The temperature during pulsing of precursor 115 can be between about 100° C. and 500° C., or about 450° C., or between about 100° C. and 400° C., or about 350° C. or between about 100° C. and 300° C., or about 250° C., or between about 100° C. and 200° C., or about 150° C. (“about” in this context means plus or minus 50° C.) or any sufficient temperature.

In an example, deposition cycle 613 of process 601 may proceed to operation 607 where oxygen species 117 may be pulsed into the chamber to form the oxide layer (e.g., oxide layer 202, 314, 414 and/or 514) on a surface (e.g., surface 153, 253) and/or within a recess on a substrate (e.g., recess 312, 412 and/or 512) on an inner surface (e.g., on inner surfaces 320, 420, and/or 520 illustrated in respective FIG. 3, FIG. 4 and FIG. 5).

In an example, oxygen species 117 may comprise a primary alcohol, a secondary alcohol, a tertiary alcohol, or the like or a combination thereof. In certain examples, oxygen species 117 may comprise one or more of: tertbutyl alcohol, methanol, ethanol, isopropanol, 1-propanol (C3H7OH), 1-butanol (C4H9OH), 1-pentanol (C5H11OH), 2-butanol (C4H10O), 2-pentanol (C5H12O), 2-hexanol (C6H14O), 2-heptanol (C7H16O), 2-methyl-2-butanol (C5H12O), 3-methyl-3-pentanol (C6H14O), 3-ethyl-3-pentanol (C7H16O), 3-methyl-3-hexanol (C7H16O), or the like, or combinations thereof.

The temperature during pulsing of oxygen species 117 can be between about 100° C. and 500° C., or about 450° C., or between about 100° C. and 400° C., or about 350° C. or between about 100° C. and 300° C., or about 250° C., or between about 100° C. and 200° C., or about 150° C. (“about” in this context means plus or minus 50° C.) or any sufficient temperature.

In some embodiments, contacting substrate 130 with an oxygen species 117 may comprise pulsing the oxygen species 117 into the reaction chamber and subsequently contacting the substrate 130 for a time period of between about 0.01 seconds and about 200 seconds, or between about 0.01 seconds and about 180 seconds, or between about 0.01 seconds and about 160 seconds, or between about 0.01 seconds and about 140 seconds, or between about 0.01 seconds and about 120 seconds, or between about 0.01 seconds and about 100 seconds, or between about 0.01 seconds and about 80 seconds, or between about 0.01 seconds and about 60 seconds, or between about 0.01 seconds and about 50 seconds, or between about 0.01 seconds and about 30 seconds, or between about 0.01 seconds and about 20 seconds, or between about 0.01 seconds and about 10 seconds, or between about 0.01 seconds and about 5.0 seconds (“about” in this context means plus or minus 10 seconds) or any other suitable duration.

In an example, deposition cycle 613 of process 601 may proceed to operation 609 where chamber 104 may be purged with purge gas 124 at various intervals (e.g., between pulses or deposition cycles). Deposition cycle 613 may be repeated any number of times until reaching a desired thickness of the oxide layer (e.g., oxide layer 202, 314, 414 and/or 514). In an example, the desired thickness may be less than about 0 angstroms, or less than about 35 angstroms, or any appropriate thickness.

In an example, the substrate comprises silicon or germanium, or a combination thereof (SiGe). In certain examples, the substrate comprises SiGe comprising a Ge concentration of about 15% to 45%. In an example, a structure formed on the substrate (e.g., substrate 130, 210, 310, 410 and/or 510 illustrated in respective FIG. 1A to FIG. 1B, FIG. 2A to FIG. 2C, FIG. 3, FIG. 4, and/or FIG. 5) may be a semiconductor device having a complementary metal-oxide-semiconductor (CMOS), a fin field-effect-transistor (finFET), a gate-all-around (GAA) transistor and/or complementary field-effect-transistor (CFET) architectures.

FIG. 6B (with reference to FIGS. 1A-5) illustrates an example process 601 for depositing an oxide on a surface (e.g., surface 153 or surface 253 shown in respective FIG. 1A to FIG. 1B and FIG. 2A to FIG. 2C,) and/or a recess of a substrate to form a semiconductor structure (e.g., structure 300, 400 and/or 500 illustrated in respective FIG. 3, FIG. 4 and FIG. 5) in accordance with examples of the disclosure. In an example, process 601 may begin at operation 602 with provision of a substrate (e.g., substrate 130, 210, 310, 410 and/or 510 illustrated in respective FIG. 1A to FIG. 1B, FIG. 2A to FIG. 2C, FIG. 3, FIG. 4, and/or FIG. 5) within a chamber (e.g., chamber 104 illustrated in FIG. 1A). The substrate may be disposed on a susceptor (e.g., susceptor 106 in FIG. 1A) for processing. The substrate may include an opening (e.g., opening 328, 428, 528 and/or 530 illustrated in respective FIG. 3, FIG. 4, and/or FIG. 5) to a recess (e.g., recess 31, 328, 428, and/or 528 illustrated in respective 1, FIG. 3, FIG. 4, and/or FIG. 5). The recess may comprise at least one opening bordered by a perimeter (e.g., perimeter 360, 460, 560, and/or 562 illustrated in respective FIG. 3, FIG. 4, and/or FIG. 5) in a surface area (e.g., surface area 332, 432, 532, and/or 533 illustrated in respective FIG. 3, FIG. 4, and/or FIG. 5) adjacent to and outside of the recess, wherein the recess comprises an inner surface (e.g., inner surface 320, 420 and/or 520 illustrated in respective FIG. 3, FIG. 4, and/or FIG. 5).

Process 601 may move to deposition cycle 612 that includes (and may or may not begin with) operation 604 where an inhibitor 121 may be pulsed into the chamber. Thus, inhibitor 121 may contact the substrate preferentially depositing the inhibitor 121 on a surface (e.g., surface 153) in the case of a planar substrate and/or proximate to and within a portion of a recess where the substrate has one or more features. For substrates having high aspect ratio features, inhibitor 121 may contact the substrate surface in a portion of the recess adjacent to at least one opening of the recess (e.g., top portions 334 or 434 and/or outer portions 534 and/or 538 illustrated in respective FIG. 3, FIG. 4, and/or FIG. 5) and on at least a portion of the surface area.

In some examples, inhibitor 121 is a growth inhibitor and comprises a vapor phase reactant. Inhibitor 121 may be a non-consumable agent that is not incorporated into the deposited film during the deposition process and helps improve the properties of the deposited film. In some examples, the growth inhibitor may comprise one or more organic molecules. In some embodiments, the inhibitor 121 may comprise an alcohol. For example, inhibitor 121 may comprise an alcohol such as tertbutyl alcohol, methanol (MeOH), ethanol (EtOH), n-propanol (n-PrOH), or butanol (t-BuOH, n-BuOH), 1-propanol (C3H7OH), 1-butanol (C4H9OH), 1-pentanol (C5H11OH), 2-butanol (C4H10O), 2-pentanol (C5H12O), 2-hexanol (C6H14O), 2-heptanol (C7H16O), 2-methyl-2-butanol (C5H12O), 3-methyl-3-pentanol (C6H14O), 3-ethyl-3-pentanol (C7H16O), 3-methyl-3-hexanol (C7H16O), or the like or a combination thereof.

In an example, by modulating inhibitor 121 exposure low (step 605), the surface area adjacent the opening to the recess (e.g., surface area 332, 432, 532 and/or 533 illustrated in respective FIG. 3, FIG. 4, and/or FIG. 5) and near the opening (e.g., top portions 334 or 434 and/or outer portions 534 and/or 538 illustrated in respective FIG. 3, FIG. 4, and/or FIG. 5) may receive a higher flux of inhibitor 121 compared to the bottom of the recess (e.g., lower portion 336, 436 illustrated in respective FIG. 3 and FIG. 4) or inner portions of the recess (e.g., inner portion 536 illustrated in FIG. 5). The term “flux” refers herein to the number of collisions of the molecules (e.g., inhibitor 121) with the surface (e.g., surface area 332), per area, per unit of time (e.g., seconds). Thus, for example, a higher flux of inhibitor 121 on surface areas 332 than on bottom surface 318 may lead to greater inhibition at surface area 332 than on bottom surface 318. This may also produce a greater inhibitory effect at the opening to the recess and/or adjacent or near the opening enabling a higher growth rate of oxide at the bottom surface (e.g., bottom surface 318 or 418 illustrated in respective FIG. 3 and FIG. 4), and/or bottom portion (e.g., lower portion 336 and/or 436 illustrated in respective FIG. 3 and FIG. 4). Likewise, with respect to structure 500, modulating inhibitor 121 exposure low may produce a greater inhibitory effect at the opening to the recess and/or adjacent the opening enabling a higher growth rate of oxide at the inner portion 536 (shown in FIG. 5) than at outer portions 534 and 538.

In an example, modulating inhibitor 121 exposure low (at step 605) may comprise selecting inhibitor 121 to have a higher molecular mass than the molecular mass of other reactants used during the deposition cycle 612 (e.g., precursor 115 and/or oxygen species 117 shown in 1)

In an example, modulating inhibitor 121 exposure low (at step 605) may comprise selecting an inhibitor 121 having a lower partial pressure than the partial pressure of other reactants used during the deposition cycle 612 (e.g., precursor 115 and/or oxygen species 117).

In an example, modulating inhibitor 121 exposure low (at step 605) may comprise selecting or tuning dilution of inhibitor 121 (e.g., dilution of inhibitor 121 with an inert species (e.g., purge gas 124)) to be greater than the dilution of other reactants used in the deposition cycle 612 (e.g., precursor 115 and/or oxygen species 117) to reduce inhibitor 121 exposure with respect to other reactants. In other words, modulating inhibitor 121 exposure low may comprise pulsing inhibitor 121 at a first concentration and pulsing the precursor 115 and/or oxygen species 117 at a second concentration, wherein the first concentration is less than the second concentration.

In an example, modulating inhibitor 121 exposure low (at step 605) may comprise selecting and/or tuning inhibitor 121 exposure time to be less than the exposure time of other reactants used during the deposition cycle 612 (e.g., precursor 115 and/or oxygen species 117). The described methods of modulating inhibitor 121 exposure low may be used in various combinations and/or separately. Moreover, the described methods of modulating inhibitor 121 may be used during deposition cycle 612 when inhibitor 121 is pulsed separately from the other reactants and/or when inhibitor 121 is pulsed simultaneously with the other reactants.

In an example, by modulating inhibitor 121 exposure low (at step 605), the areas adjacent to the recess opening (e.g., surface areas 332, 432, 532 and/or 533 and/or top portions 334, 434, and/or outer portions 534, 538, illustrated in respective FIG. 3, FIG. 4 and FIG. 5) may receive a higher flux of inhibitor 121 compared to a lower flux of inhibitor 121 received by the lower or inner portions or bottom surface of the recess (e.g., bottom surfaces 318, 418 and/or lower portions 336, 436, and/or inner portion 536). This produces a greater inhibition effect in those areas receiving the higher flux of inhibitor 121 thus enabling a higher growth rate of an oxide in those areas receiving the lower flux of inhibitor 121 upon exposure of the substrate to precursor 115 and/or oxygen species 117 (as described in greater detail below) during deposition cycle 612.

It shall be understood that the application of inhibitor 121 results in an inhibition of the proximal regions of the recess (e.g., recess 31, 328, 428, and/or 528 illustrated in respective 1, FIG. 3, FIG. 4, and/or FIG. 5). Proximal regions of recess are areas of the recess and opening having greater exposure to inhibitor 121 during deposition cycle 612 (e.g., surface areas 332, 432 and/or 532, 533, top portions 334, 434, and/or outer portions 534, 538). Whereas distal regions of the recess are areas of the recess having less exposure to inhibitor 121 during deposition cycle 612 (e.g., including bottom surfaces 318, 418 and/or lower portions 336, 436, and/or inner portion 536).

In an example, distal regions may be left substantially unaffected, or at least less affected than the proximal regions. In other words, the proximal regions can be suitably rendered less reactive towards a precursor 115 that can be subsequently provided to the reaction chamber. Moreover, contacting the substrate with inhibitor 121 can result in an inhibition gradient in the recess feature. Such a gradual change of inhibitory intensity may decrease from surface areas (e.g., surface area 332, 432, 532 and/or 533 illustrated in respective FIG. 3, FIG. 4, and/or FIG. 5) around the opening to the recess towards the bottom of the recess (e.g., lower portion 336, 436 illustrated in respective FIG. 3 and FIG. 4) or inner portions of the recess (e.g., inner portion 536 illustrated in FIG. 5). Thus, the inhibition is stronger in the proximal region of the recess than in the distal region of the recess. As exposure of inhibitor 121 decreases adsorption of inhibitor 121 decreases thus inhibition gradually decreases. Therefore, an inhibition gradient results going from the stronger inhibition in the proximal region of the recess to weaker inhibition in the distal region of the recess.

In an example, inhibitor 121 can be pulsed into the reaction chamber for any suitable duration (e.g., for pulse times of between 0.05 to 200 seconds). The pressure within the reaction chamber during provision of inhibitor 121 can be any suitable pressure, such as between 1 and 10 Torr. The temperature during pulsing of inhibitor 121 can be between about 100° C. and 500° C., or about 450° C., or between about 100° C. and 400° C., or about 350° C. or between about 100° C. and 300° C., or about 250° C., or between about 100° C. and 200° C., or about 150° C. (“about” in this context means plus or minus 50° C.) or any sufficient temperature.

In an example, deposition cycle 612 of process 601 may move to operation 606 where a precursor 115 may be pulsed into the chamber where the precursor 115 may chemisorb to the inner surface (e.g., inner surface 320, 420, and/or 520 illustrated in respective FIG. 3, FIG. 4, and/or FIG. 5) within the recess.

In an example, precursor 115 can be provided through a showerhead (e.g., showerhead 108 illustrated in 1) to the substrate, or through a crossflow fluid distribution system. In an example, precursor 115 may be a metal-containing precursor for forming of metal or metallic oxides including but not limited to magnesium oxide (MgO), aluminum oxide (Al2O3), zirconium oxide (ZrO2), hafnium oxide (HfO2), hafnium silicon oxide (HfSiO), tantalum oxide (Ta2O5), tantalum silicon oxide (TaSiO), titanium dioxide (TiO2), zinc oxide (ZnO), barium strontium titanate (BST), and strontium bismuth tantalate (SBT). Such precursors may comprise, for example, trimethylaluminum (TMA), dimethylaluminum hydride (DMAH), dimethylaluminum isopropoxide (DMAI), dimethylethylaminealane (DMEAA), trimethylaminealane (TEAA), N-methylpyrroridinealane (MPA), tri-isopropoxide aluminum, tri-isobutylaluminum (TIBA), and tritertbutylaluminum (TTBA), diethyl zinc (DEZ), tetraisopropyl orthotitanate (TTIP), titanium tetrachloride (TiCl4), tetrakis (dimethylamino) titanium (TDMAT), tetrakis(dimethylamino)zirconium (IV) (TDMAZ), magnesocene (Mg—(Cp)2), dimethylzinc (ZnMe2), diethylzinc (ZnEt2), methylzinc isopropoxide (ZnMe(OPr)), or zinc acetate (Zn(CH3CO2)2, halfnium chloride (HfCl4), and/or zirconium(IV) chloride (ZrCl4), or the like or combinations thereof, or any other appropriate precursor.

In other examples, precursor 115 may be a lanthanide-containing precursor for forming of lanthanide oxides, i.e., oxides of physically stable “rare earth” metallic elements such as scandium (Sc), yttrium (Y), lanthanum (La), cerium Ce, praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb) and lutetium (Lu), as well as silicon nitride (SiN). Such precursors may comprise, for example, 2,2,6,6-tetramethyl-3,5-heptane-dionate(III) lanthanum (La(thd)3), tris(cyclopentadienyl)lanthanum(III) (La(Cp)3), tris(isopropylcyclopentadienyl)lanthanum(III) (La(iPrCp)3) and/or tris(N,N′-diisopropylacetamidinato)scandium (Sc(amd)3), or the like or combinations thereof, or any other appropriate precursor.

In an example, precursor 115 can be pulsed into the reaction chamber for any suitable duration (e.g., for pulse times of between 0.05 to 200 seconds). The pressure within the reaction chamber during provision of precursor 115 can be any suitable pressure, such as between 1 and 10 Torr. The temperature during pulsing of precursor 115 can be between about 100° C. and 500° C., or about 450° C., or between about 100° C. and 400° C., or about 350° C. or between about 100° C. and 300° C., or about 250° C., or between about 100° C. and 200° C., or about 150° C. (“about” in this context means plus or minus 50° C.) or any sufficient temperature.

In an example, deposition cycle 612 of process 601 may proceed to operation 608 where oxygen species 117 may be pulsed into the chamber to form the oxide layer (e.g., oxide layer 202, 314, 414 and/or 514) on the surface 253 or within the recess (e.g., recess 312, 412 and/or 512) or on inner surfaces (e.g., on inner surfaces 320, 420, and/or 520 illustrated in respective FIG. 3, FIG. 4 and FIG. 5).

Operation 608 may take place within the same or a different chamber as operation 604 and/or operation 606. Oxide layer (e.g., oxide layer 314, 414 and/or 514 illustrated in respective FIG. 3, FIG. 4, and/or FIG. 5) may be formed responsive to oxygen species 117 contacting chemisorbed precursor 115 deposited on the inner surface of the substrate (i.e., upon contact with the chemisorbed precursor). Over a number of repeating deposition cycles 612 the oxide layer may fill the recess (e.g., recess 312, 412, and/or 512 illustrated in respective FIG. 3, FIG. 4, and/or FIG. 5). Inhibitor 121 will not substantially participate in film growth of the oxide layer and not incorporate in growing film. As noted previously, because more precursor 115 may be chemisorbed in the distal region of the recess compared to the proximate region, an oxide layer may be formed more readily and grow more rapidly in the distal region compared to the proximal region over one or more deposition cycles 612. Thus, an oxide layer (e.g., oxide layer 314 and/or 414 illustrated in respective FIG. 3 and FIG. 4) may be grown in a bottom-up way and/or may be grown from a side surface (e.g., side surface 516 illustrated in FIG. 5) inward.

Various inhibitors 121 may have some reactivity with surfaces within the recess. For example, alkyl alcohols may have surface reactivity. In such a case, inhibitor 121 can be selected to be less reactive and produce lower growth rate than oxygen species 117 and/or inhibitor 121 exposure can be tuned low to saturate only the proximal region of the structure (e.g., structures 300, 400, and 500) at low growth rate while a higher reactivity oxidizer, oxygen species 117, may be pulsed at full saturating exposure creating a high(er) growth rate of oxide (e.g., oxide layer 314, 414, and/or 514) at the distal portion of the recess.

In some examples, oxygen species 117 and inhibitor 121 may be pulsed simultaneously during one or more deposition cycles 612. In the case of mixed oxygen species 117 (e.g., H₂O) and inhibitor 121 (e.g., alkyl alcohol) where inhibitor 121 is less reactive and/or produces lower growth rate than oxygen species 117, the inhibitor 121 exposure may be modulated to tune exposure low to saturate only the proximal region of the structure (e.g., structures 300, 400, and 500) at low growth rate while a higher reactivity oxidizer, oxygen species 117, may be pulsed at full saturating exposure creating a high(er) growth rate of oxide (e.g., oxide layer 314, 414, and/or 514) at the distal portion of the recess.

In an example, modulating the inhibitor 121 exposure low (at step 605) when pulsing the inhibitor 121 and the oxygen species 117 simultaneously may comprise selecting the inhibitor to have a first partial pressure below a second partial pressure of the oxygen species 117.

In an example, modulating the inhibitor 121 exposure low (at step 605) when pulsing the inhibitor 121 and the oxygen species 117 simultaneously may comprise selecting the inhibitor 121 to have a first molecular mass greater than a second molecular mass of the oxygen species 117.

In an example, modulating the inhibitor 121 exposure low (at step 605) when pulsing the inhibitor 121 and the oxygen species 117 simultaneously may comprise pulsing the inhibitor 121 at a first concentration and pulsing the oxygen species 117 at a second concentration, wherein the first concentration is less than the second concentration.

The described methods of modulating inhibitor 121 exposure low at step 605 when pulsing inhibitor 121 and the oxygen species 117 simultaneously may be used in various combinations and/or separately.

In an example, oxygen species 117 may comprise an alcohol, such as, for example, a primary alcohol, secondary alcohol, tertiary alcohol, or the like or a combination thereof. In certain examples, oxygen species 117 may comprise one or more of: tertbutyl alcohol, methanol, ethanol, isopropanol, 1-propanol (C3H7OH), 1-butanol (C4H9OH), 1-pentanol (C5H11OH), 2-butanol (C4H10O), 2-pentanol (C5H12O), 2-hexanol (C6H14O), 2-heptanol (C7H16O), 2-methyl-2-butanol (C5H12O), 3-methyl-3-pentanol (C6H14O), 3-ethyl-3-pentanol (C7H16O), 3-methyl-3-hexanol (C7H16O), or the like, or combinations thereof.

The temperature during pulsing of oxygen species 117 can be between about 100° C. and 500° C., or about 450° C., or between about 100° C. and 400° C., or about 350° C. or between about 100° C. and 300° C., or about 250° C., or between about 100° C. and 200° C., or about 150° C. (“about” in this context means plus or minus 50° C.) or any sufficient temperature.

In an example, the oxide layer may be formed to a thickness sufficient to fill the recess.

The steps of pulsing precursor 115, oxygen species 117 and inhibitor 121 in respective operations 604, 606 and 608 can be performed in any appropriate order. In various examples, the steps of providing precursor 115, oxygen species 117 and inhibitor 121 can each be separated by a purge gas 124 (operation 610) to remove excess precursor, byproducts, or other unwanted materials. In various examples, a purge gas can be provided after each operation (e.g., after pulsing precursor 115, oxygen species 117 and/or inhibitor 121, regardless of the order) and/or after deposition of the oxide layer (e.g., oxide layer 314, 414, and/or 514).

In various examples, the steps of providing precursor 115, oxygen species 117 and inhibitor 121 can be performed in any suitable order. For example, one or more of the steps of pulsing precursor 115, oxygen species 117 and inhibitor 121 can be performed sequentially and/or simultaneously. One or more steps of pulsing precursor 115, oxygen species 117 and/or inhibitor 121 into the chamber may be separated by a purge gas 124 to remove excess precursor, byproducts, or other unwanted materials. In various examples, a purge gas 124 can be provided after each step (e.g., after providing the precursor 115 and providing the oxygen species 117, regardless of the order) and/or after each deposition cycle 612 and/or after deposition of the oxide or after a deposition of inhibitor.

In some embodiments, contacting substrate 130 with an oxygen species 117 may comprise pulsing the oxygen species 117 into the reaction chamber and subsequently contacting the substrate 130 for a time period of between about 0.01 seconds and about 200 seconds, or between about 0.01 seconds and about 180 seconds, or between about 0.01 seconds and about 160 seconds, or between about 0.01 seconds and about 140 seconds, or between about 0.01 seconds and about 120 seconds, or between about 0.01 seconds and about 100 seconds, or between about 0.01 seconds and about 80 seconds, or between about 0.01 seconds and about 60 seconds, or between about 0.01 seconds and about 50 seconds, or between about 0.01 seconds and about 30 seconds, or between about 0.01 seconds and about 20 seconds, or between about 0.01 seconds and about 10 seconds, or between about 0.01 seconds and about 5.0 seconds (“about” in this context means plus or minus 10 seconds) or any other suitable duration.

Pulsing of precursor 115, oxygen species 117 and inhibitor 121 may be alternating, sequential, and/or simultaneous. One or more of precursor 115, oxygen species 117 and inhibitor 121 may be pulsed over about 1 cycle to about 200 cycles, or about 1 cycle to about 180 cycles, or about 1 cycle to about 160 cycles, or about 1 cycle to about 140 cycles, or about 1 cycle to about 120 cycles, or about 1 cycle to about 100 cycles, or about 1 cycle to about 80 cycles, or about 1 cycle to about 60 cycles, or about 1 cycle to about 40 cycles, or about 1 cycle to about 20 cycles, about 1 cycle to about 5 cycles, (“about” in this context means plus or minus 20 cycles) or any suitable number of cycles.

FIG. 7 illustrates an example process 700 for forming a semiconductor structure in accordance with examples of the disclosure. In an example, process 700 may begin at operation 702 with provision of a substrate 710 within a chamber (e.g., chamber 104 illustrated in 1).

Substrate 710 may be disposed on a susceptor (e.g., susceptor 106 in 1) for processing. Substrate 710 may include at least one opening 728 to a recess 712. In an example, opening 728 is bordered by a perimeter in surface area 732. Recess 712 comprises an inner surface 720.

Process 700 may move to operation 704 where a metal oxide deposition cycle 612 (see 6) may include pulsing of inhibitor 121 into the chamber where inhibitor 121 may contact substrate 710. In some examples, inhibitor 121 is a growth inhibitor as described above in more detail. In an example, exposure by inhibitor 121 is modulated to provide a higher exposure level of inhibitor 121 to the area near the opening 728 to recess 712 including surface area 732 and top portions 734 to promote a higher flux of inhibitor 121 compared to the bottom portion 736 of recess 712. This may produce a greater inhibitory effect at the opening 728 to the recess and/or near the opening 728 enabling a higher growth rate of oxide at the bottom surface 718, and/or bottom portion 736. In an example, modulating inhibitor 121 exposure low may be tuned to gradually reduce the exposure of substrate 710 to inhibitor over the course of process 700.

In an example, inhibitor 121 can be pulsed into the reaction chamber for any suitable duration (e.g., for pulse times of between 0.05 to 200 seconds).

Operation 704 may continue with pulsing precursor 115 into the chamber where the precursor 115 may chemisorb to the inner surface 720 within the recess 712.

In an example, precursor 115 can be provided through a showerhead (e.g., showerhead 108 illustrated in 1) to the substrate, or through a crossflow fluid distribution system. In an example, precursor 115 may be a precursor as described above.

In an example, exposing the substrate to precursor 115 may result in a gradual change in the density of chemisorbed precursor 115 per unit area from greater chemisorption in the distal region 750 to weaker (or less) chemisorption in the proximal region 752. Subsequently exposing the substrate to an oxygen reactant then allows oxygen-containing species to react with the chemisorbed precursor to form a metal oxide. Because more precursor 115 may be chemisorbed in the distal region 750 compared to the proximate region 752, more metal oxide may be formed in the distal region compared to the proximal region. In other words, the metal oxide may be grown in a bottom-up way.

In an example, operation 704 may continue with pulsing oxygen species 117 into the chamber to contact substrate surfaces 720.

Oxide layer 714 may begin to form responsive to oxygen species 117 contacting chemisorbed precursor 115 deposited on the inner surface of the substrate.

Process 700 may proceed through operations 706-710 where deposition cycles 612 may be repeated a number of time sufficient for Oxide layer 714 to fill recess 712 substantially free of gaps or seams.

FIG. 8 illustrates an example process 800 for forming a semiconductor structure in accordance with examples of the disclosure. In an example, process 800 may begin at operation 802 with provision of a substrate 810 within a chamber (e.g., chamber 104 illustrated in 1).

Substrate 810 may be disposed on a susceptor (e.g., susceptor 106 in 1) for processing. Substrate 810 may include at least one opening 828 to a recess 812. In an example, opening 828 is bordered by a perimeter in surface area 832. Recess 812 comprises an inner surface 820. Recess 812 may be an inverse taper shape.

Process 800 may move to operation 804 where a metal oxide deposition cycle 612 (see 6) may include pulsing of inhibitor 121 into the chamber where inhibitor 121 may contact substrate 810. In some examples, inhibitor 121 is a growth inhibitor as described above in more detail. In an example, exposure by inhibitor 121 is modulated to provide a higher exposure level of inhibitor 121 to the area near the opening 828 to recess 812 including perimeter area 832 and top portions 834 to promote a higher flux of inhibitor 121 compared to the bottom portion 836 of recess 812. This may produce a greater inhibitory effect at the opening 828 to the recess and/or near the opening 828 enabling a higher growth rate of oxide at the bottom surface 818, and/or bottom portion 836. In an example, modulating inhibitor 121 exposure low may be tuned to gradually reduce the exposure of substrate 810 to inhibitor over the course of process 800.

In an example, inhibitor 121 can be pulsed into the reaction chamber for any suitable duration (e.g., for pulse times of between 0.05 to 200 seconds).

Operation 804 may continue with pulsing precursor 115 into the chamber where the precursor 115 may chemisorb to the inner surface within the recess.

In an example, precursor 115 can be provided through a showerhead (e.g., showerhead 108 illustrated in 1) to the substrate, or through a crossflow fluid distribution system. In an example, precursor 115 may be a precursor as described above.

In an example, exposing the substrate to a precursor 115 after exposing substrate 810 to inhibitor 121 may result in a gradual change in the density of chemisorbed precursor 115 per unit area from greater chemisorption in the distal region 850 to weaker (or less) chemisorption in the proximal region 852. Subsequently exposing the substrate to an oxygen reactant then allows oxygen-containing species to react with the chemisorbed precursor to form a metal oxide. Because more precursor 115 may be chemisorbed in the distal region 850 compared to the proximate region 852, more metal oxide may be formed in the distal region compared to the proximal region. In other words, the metal oxide may be grown in a bottom-up way.

In an example, operation 804 may continue with pulsing oxygen species 117 into the chamber to contact substrate surfaces 820.

Oxide layer 814 may begin to form responsive to oxygen species 117 contacting chemisorbed precursor 115 deposited on the inner surface of the substrate.

Process 800 may proceed through operations 806-810 where deposition cycles 612 may be repeated a number of time sufficient for Oxide layer 814 to fill recess 812 substantially free of gaps or seams.

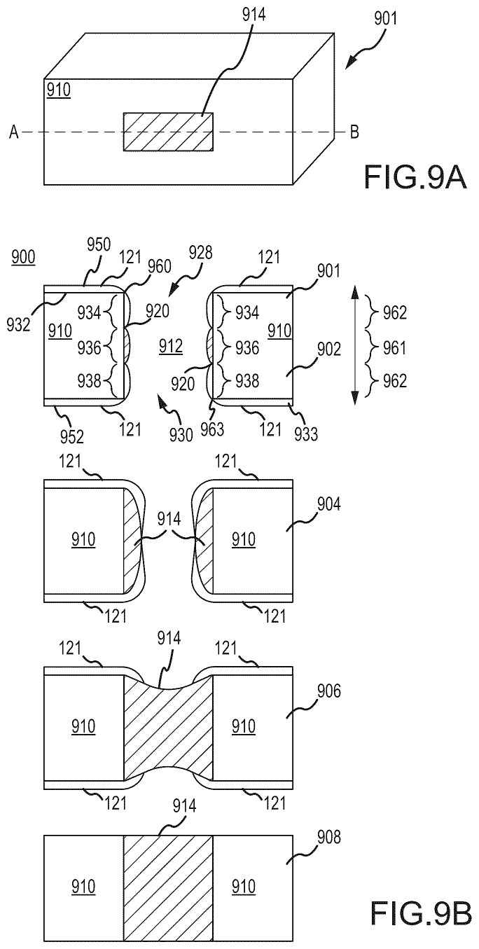

FIG. 9A illustrates a structure 901 in accordance with examples of the disclosure. Device structure 901 can be any of a variety of semiconductor structures (e.g., gate-all-around (GAA) structure). In various examples, various features may be formed into or onto a surface of substrate 910 (e.g., a three-dimensional structure such as a hole or via). Such a patterned substrate 910 may comprise partially fabricated semiconductor device structures, such as, for example, transistors (e.g., such as FinFETS or gate-all-around (GAA) FETS) and/or memory elements. In some examples the structures may have high aspect ratios (e.g., aspect ratios of about 4 or higher) or complex morphology.

FIG. 9B illustrates an example process 900 for forming a semiconductor structure 901 in accordance with examples of the disclosure. Cross-sectional view A-B from FIG. 9A is shown with process operations 902-908 in 9.

In an example, process 900 may begin at operation 902 with provision of a substrate 910 within a chamber (e.g., chamber 104 illustrated in 1). In an example, structure 901 includes a recess 912. Recess 912 may have outer portions 934 and 938 and an inner portion 936.
at least one opening 928 to a recess 812. In an example, opening 828 is bordered by a perimeter in surface area 832. Recess 812 comprises an inner surface 820. Recess 812 may be an inverse taper shape.

Substrate 910 may include an opening bordered on a first side 950 by a perimeter 960 in surface area 932. On an opposite side 952, recess 912 may be bordered by perimeter 963 in surface area 933. Surface area 932 may be disposed in a plane about perimeter 960 of recess 912 proximate opening 928. Surface area 933 may be disposed in a plane about perimeter 963 of recess 912 near opening 930. Recess 912 may also include an inner sidewall surface 920 comprising sidewalls surfaces. Recess 912 may extend from opening 928 through to opening 930 to form a hole or via in substrate 910. Opposing sidewall surfaces 920 may be parallel or have a different geometry. Structure 901 may be formed according to examples described herein.

Process 900 may move to operation 904 where an oxide deposition cycle 612 (see 6) may include pulsing of inhibitor 121 into the chamber where inhibitor 121 may contact substrate 910. In some examples, inhibitor 121 is a growth inhibitor as described above in more detail. In an example, exposure by inhibitor 121 is modulated to provide a higher exposure level of inhibitor 121 to the area near the openings 928 and 930 to recess 912 including surface area 932 and outside portions 934 and 938 to promote a higher flux of inhibitor 121 compared to the inner portion 936 of recess 912. This may produce a greater inhibitory effect at the openings 928 and 930 to the recess and/or near the openings enabling a higher growth rate of oxide at the inner sidewall surface 920 at inner portion 936.

In an example, inhibitor 121 can be pulsed into the reaction chamber for any suitable duration (e.g., for pulse times of between 0.05 to 200 seconds).

Operation 804 may continue with pulsing precursor 115 into the chamber where the precursor 115 may chemisorb to the inner surface within the recess.

In an example, precursor 115 can be provided through a showerhead (e.g., showerhead 108 illustrated in 1) to the substrate, or through a crossflow fluid distribution system. In an example, precursor 115 may be a precursor as described above.

In an example, exposing the substrate to a precursor 115 after exposing substrate 910 to inhibitor 121 may result in a gradual change in the density of chemisorbed precursor 115 per unit area from greater chemisorption in the distal region 961 to weaker (or less) chemisorption in the proximal regions 962. Subsequently exposing the substrate to an oxygen species 117 then allows oxygen-containing species to react with the chemisorbed precursor to form an oxide. Because more precursor 115 may be chemisorbed in the distal region 961 compared to the proximal region 962, more oxide may be formed in the distal region 961 per deposition cycle 612 compared to the proximal region 962. Thus, the oxide may be grown inward from the inner side walls surface 920 substantially without seams or gaps.

In an example, operation 904 may continue with pulsing oxygen species 117 into the chamber to contact sidewall surface 920. Oxide layer 914 may begin to form responsive to oxygen species 117 contacting chemisorbed precursor 115 deposited on the inner surface of the substrate.

Process 900 may proceed through operations 906-908 where deposition cycles 612 may be repeated a number of time sufficient for Oxide layer 914 to fill recess 912 substantially free of gaps or seams.

Although exemplary examples of the present disclosure are set forth herein, it should be appreciated that the disclosure is not so limited. Various modifications, variations, and enhancements of the system and method set forth herein may be made without departing from the spirit and scope of the present disclosure.

The subject matter of the present disclosure includes all novel and nonobvious combinations and subcombinations of the various systems, components, and configurations, and other features, functions, acts, and/or properties disclosed herein, as well as any and all equivalents thereof.

What is claimed is:

1. A method for depositing an oxide in a recess of a substrate, comprising:
a) providing the substrate in a chamber, the substrate including at least one opening to the recess wherein the at least one opening is bordered by a perimeter in a surface area adjacent to and outside of the recess, wherein the recess comprises an inner surface;
b) pulsing a precursor into the chamber to chemisorb to the inner surface within the recess;
c) pulsing an oxygen species comprising a first alcohol into the chamber to form the oxide within the recess upon contact with the chemisorbed precursor;
d) pulsing an inhibitor into the chamber to preferentially deposit the inhibitor in a portion of the recess adjacent to the at least one opening and on at least a portion of the surface area; and
e) repeating steps b)-d) to deposit the oxide to a desired thickness level within the recess.

2. The method of claim 1, wherein the inhibitor is a second alcohol.

3. The method of claim 2, wherein the oxide is a metal oxide.

4. The method of claim 2, wherein pulsing the inhibitor to preferentially deposit the inhibitor at the at least one opening further comprises pulsing the inhibitor for a first time period and pulsing the oxygen species for a second time period, wherein the first time period is shorter than the second time period.

5. The method of claim 2, wherein pulsing the inhibitor to preferentially deposit the inhibitor further comprises selecting the inhibitor to have a first partial pressure below a second partial pressure of the oxygen species.

6. The method of claim 5, further comprising adding an inert gas pulse to an inhibitor pulse or an oxygen species pulse to tune the first partial pressure or the second partial pressure.

7. The method of claim 1, wherein pulsing the inhibitor to preferentially deposit the inhibitor further comprises pulsing the inhibitor at a first concentration and pulsing the oxygen species at a second concentration, wherein the first concentration is less than the second concentration.

8. The method of claim 1, wherein the inhibitor and the oxygen species are both tertbutyl alcohol.

9. The method of claim 1, further comprising pulsing the inhibitor and the oxygen species simultaneously.

10. The method of claim 9, wherein pulsing the inhibitor and the oxygen species simultaneously further comprises selecting the inhibitor to have a first partial pressure below a second partial pressure of the oxygen species, wherein the first partial pressure and the second partial pressure are between 10 mTorr to 1 Torr.

11. The method of claim 9, wherein pulsing the inhibitor and the oxygen species simultaneously further comprises selecting the inhibitor to have a first molecular mass greater than a second molecular mass of the oxygen species.

12. The method of claim 9, wherein pulsing the inhibitor and the oxygen species simultaneously further comprises pulsing the inhibitor at a first concentration and pulsing the oxygen species at a second concentration, wherein the first concentration is less than the second concentration, wherein the first concentration and the second concentration are between 1% to 50%.

13. The method of claim 12, further comprising depositing a higher flux of the inhibitor proximate the at least one opening on at least a portion of the perimeter surface area compared to a bottom surface or opposing side walls, or a combination thereof.

14. A method for depositing an oxide on a substrate, comprising:
a) providing the substrate in a chamber;
b) initially pulsing a precursor into the chamber to chemisorb a constituent onto a surface of the substrate;
c) pulsing an oxygen species into the chamber to form an oxide layer on the surface upon contact with the constituent, wherein the oxygen species comprises an alcohol; and
d) repeating one or more steps b)-c) until the oxide layer is deposited to a desired thickness.

15. The method of claim 14, wherein the substrate comprises silicon or germanium, or a combination thereof (SiGe).

16. The method of claim 15, wherein the substrate comprises SiGe having a Ge concentration of 15% to 45%.

17. The method of claim 14, wherein the precursor is a metal-containing precursor.

18. The method of claim 14, wherein the oxide is a metal oxide.

19. The method of claim 14, wherein the alcohol is tertbutyl alcohol, methanol (MeOH), ethanol (EtOH), n-propanol (n-PrOH), or butanol (t-BuOH, n-BuOH), 1-propanol (C3H7OH), 1-butanol (C4H9OH), 1-pentanol (C5H11OH), 2-butanol (C4H10O), 2-pentanol (C5H12O), 2-hexanol (C6H14O), 2-heptanol (C7H16O), 2-methyl-2-butanol (C5H12O), 3-methyl-3-pentanol (C6H14O), 3-ethyl-3-pentanol (C7H16O), 3-methyl-3-hexanol (C7H16O), or a combination thereof.

20. The method of claim 14, wherein the desired thickness is less than 50 angstroms.
